(19) United States
(12) Patent Application Publication
(10) Pub. No.: US 2009/0114977 A1
(43) Pub. Date: May 7, 2009

(54) NONVOLATILE MEMORY DEVICE HAVING CHARGE TRAPPING LAYER AND METHOD FOR FABRICATING THE SAME

(75) Inventors: Ki Seon Park, Yongin-si (KR); Moon Sig Joo, Icheon-si (KR); Yong Top Kim, Seoul (KR); Jae Young Park, Icheon-si (KR); Ki Hong Lee, Suwon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,177

(22) Filed: Jun. 26, 2008

(30) Foreign Application Priority Data
Nov. 7, 2007 (KR) 10-2007-0112956

(51) Int. Cl. H01L 29/792; H01L 21/28

(52) U.S. Cl. 257/326; 438/591; 257/E29.309; 257/E21.21

(57) ABSTRACT

Disclosed herein is a nonvolatile memory device having a charge trapping layer and a method of making the same. The nonvolatile memory device includes a substrate, a tunneling layer disposed on the substrate, a charge trapping layer disposed on the tunneling layer, a first blocking layer disposed on the charge trapping layer, a second blocking layer disposed on the first blocking layer, and a control gate electrode disposed on the second blocking layer. A first band gap between the first blocking layer and the charge trapping layer is larger than a second band gap between the second blocking layer and the charge trapping layer.

### CROSS-REFERENCE TO RELATED APPLICATION

The priority of Korean patent application number 10-2007-0112956, filed on Nov. 7, 2007, the disclosure of which is incorporated by reference in its entirety. is claimed.

### BACKGROUND OF THE INVENTION

1. Field of the Invention

The present invention relates generally to a nonvolatile memory device, and more particularly, to a nonvolatile memory device having a charge trapping layer and a method for fabricating the same.

2. Brief Description of Related Technology

Generally, semiconductor memory devices for storing data are classified into a volatile memory device and a non-volatile memory device. A volatile memory device loses its stored data when power is interrupted, but a non-volatile memory device retains its stored data even when power is interrupted. Accordingly, a non-volatile memory device is extensively used in a mobile phone system, a memory card for storing music and/or image data, and other applicable devices under conditions where power may not be always supplied or low power is required.

A cell transistor of a nonvolatile memory device typically has a floating gate structure. The floating gate structure includes a gate insulating layer, a floating gate electrode, an inter-gate insulating layer, and a control gate electrode, which are sequentially stacked in a channel region of the cell transistor. However, as the integration density of semiconductor memory device increases, the floating gate structure suffers from interference phenomena. Due to the interference phenomena, there is a limitation in increasing the integration density of the semiconductor memory device. There is an increasing interest in nonvolatile memory devices that have charge trapping layers because interference phenomena are less frequent in these devices.

The nonvolatile memory device having the charge trapping layer includes a tunneling layer, a charge trapping layer, a blocking layer, and a control gate electrode, which are sequentially stacked on a substrate having a channel region. If the control gate electrode is positively charged and a proper bias is applied to an impurity region, then hot electrons from the substrate are trapped in trap sites within the charge trapping layer. In this way, a write operation or a program operation is carried out. On the other hand, if the control gate electrode is negatively charged and a proper bias is applied to the impurity region, then holes from the substrate are trapped in trap sites within the charge trapping layer. The holes trapped in the charge trapping layer are recombined with extra electrons existing in the trap sites. In this way, an erase operation is carried out.

Many recent studies and experiments show that nonvolatile memory devices have excellent operation characteristics. However, in order to apply the nonvolatile memory devices to actual products, there is a need to address the degradation of retention characteristic (charge storage characteristic) of the charge trapping layer, which is caused by the repetitive cycles of operations such as a program operation or an erase operation. It has been known that the degradation of the retention characteristic has a close relation to leakage current characteristic caused by physical properties of layers included in the nonvolatile memory device.

### SUMMARY OF THE INVENTION

Disclosed herein is a nonvolatile memory device having enhanced retention characteristics in that it prevents electrons trapped in a charge trapping layer from leaking toward a blocking layer. Also disclosed herein is a method for fabricating the nonvolatile memory device.

In one embodiment, the device includes: a substrate; a tunneling layer disposed on the substrate; a charge trapping layer disposed on the tunneling layer; a first blocking layer disposed on the charge trapping layer; a second blocking layer disposed on the first blocking layer; and a control gate electrode disposed on the second blocking layer. In particular, a first band gap between the first blocking layer and the charge trapping layer is larger than a second band gap between the second blocking layer and the charge trapping layer.

In another embodiment, the device includes: a silicon substrate; an oxide layer disposed on the silicon substrate; a silicon nitride layer disposed on the oxide layer; a silicon oxynitride layer and an aluminum oxide layer disposed on the silicon nitride layer; and a polysilicon layer disposed on the aluminum oxide layer.

In a further embodiment, the device includes: a silicon substrate; an oxide layer disposed on the silicon substrate; a silicon nitride layer disposed on the tunneling layer; a silicon oxynitride layer and an aluminum oxide layer disposed on the silicon nitride layer; and a metal layer disposed on the aluminum oxide layer.

In still another embodiment, a method for fabricating a nonvolatile memory device includes: forming a tunneling layer on a substrate; forming a charge trapping layer on the tunneling layer; forming a first blocking layer on the charge trapping layer; forming a second blocking layer on the first blocking layer; and forming a control gate electrode on the second blocking layer, wherein a first band gap between the first blocking layer and the charge trapping layer is larger than a second band gap between the second blocking layer and the charge trapping layer.

In yet another embodiment, a method for fabricating a nonvolatile memory device includes: forming a tunneling layer on a substrate; forming a charge trapping layer on the tunneling layer; oxidizing the charge trapping layer by a predetermined thickness to form a first blocking layer; forming a second blocking layer on the first blocking layer; and forming a control gate electrode on the second blocking layer.

Additional features of the disclosed invention may become apparent to those skilled in the art from a review of the following detailed description, taken in conjunction with the drawings, and the appended claims.

### BRIEF DESCRIPTION OF THE DRAWINGS

For a more complete understanding of the disclosure, reference should be made to the following detailed description and accompanying drawings wherein:

FIG. 1 illustrates a sectional view of a nonvolatile memory device having a charge trapping layer according to an embodiment of the present invention;

FIG. 2 is a band diagram of the device illustrated in FIG. 1;

FIG. 3 is a graph showing a retention characteristic of the device of FIG. 1; and,

FIGS. 4 to 6 illustrate a method for fabricating the device of FIG. 1.

While the disclosed device and method are susceptible of embodiments in various forms, there are illustrated in the drawings (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

Hereinafter, a nonvolatile memory device having a charge trapping layer and a method for fabricating the same in accordance with the present invention will be described in detail with reference to the accompanying drawings.

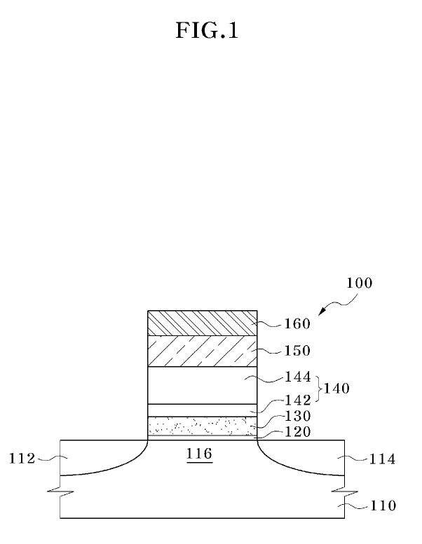

FIG. 1 illustrates a sectional view of a nonvolatile memory device 100 having a charge trapping layer according to an embodiment of the present invention. The device 100 includes a charge trapping layer 130 disposed on a substrate 110. The substrate 110 may be, but is not limited to, a silicon substrate. A first impurity region 112 and a second impurity region 114 are defined in predetermined upper portions of the substrate 110 and spaced apart from each other by a channel region 116. A tunneling layer 120 is disposed between the substrate 110 and the charge trapping layer 130. The tunneling layer 120 functions to make carriers of the channel region 116 penetrate into the charge trapping layer 130 under a predetermined condition. The tunneling layer 120 may include an oxide layer.

The charge trapping layer 130 has a thickness ranging from approximately 40 Å to approximately 100 Å. In one example, the charge trapping layer 130 includes a stoichiometric silicon nitride (Si₃N₄) layer. The charge trapping layer 130 may include a stoichiometric silicon nitride (Si₃N₄) layer and a silicon-rich silicon nitride (SiₓN_{y}) layer. The silicon-rich silicon nitride (SiₓN_{y}) layer represents that a composition ratio of silicon (Si) to nitride (N) is relatively larger than that of the stoichiometric silicon nitride (Si₃N₄). Also, the stoichiometric silicon nitride (Si₃N₄) may be disposed under the silicon-rich silicon nitride (SiₓN_{y}) or above the silicon-rich silicon nitride (SiₓN_{y}). The charge trapping layer 130 may have a stacked structure of a lower stoichiometric silicon nitride (Si₃N₄) layer, a silicon-rich silicon nitride (SiₓN_{y}) layer, and an upper stoichiometric silicon nitride (Si₃N₄) layer. In any case, the composition ratio of silicon (Si) to nitride (N) in the silicon-rich silicon nitride (SiₓN_{y}) layer is in a range from approximately 1:0.8 to approximately 1:1.3.

A blocking layer 140 is disposed on the charge trapping layer 130. The blocking layer 140 includes a first blocking layer 142 and a second blocking layer 144, which are stacked in this order. The first blocking layer 142 is formed of a material having a first band gap with respect to the charge trapping layer 130. The second blocking layer 144 is formed of a high-k material having a second band gap with respect to the charge trapping layer 130. Specifically, the first band gap between the first blocking layer 142 and the charge trapping layer 130 is larger than the second band gap between the second blocking layer 144 and the charge trapping layer 130. The first blocking layer 142 may include a silicon oxynitride (SiON) layer having a thickness ranging from approximately 30 Å to approximately 60 Å. The second blocking layer 144 may include an aluminum oxide (Al₂O₃) layer having a thickness ranging from approximately 40 Å to approximately 300 Å. Also, the second blocking layer 144 may include a hafnium oxide (HfO₂) layer, a hafnium aluminum oxide (HfAlO) layer, a hafnium silicon oxide (HfSiO) layer, a hafnium lanthanum oxide (HfLaO) layer, a zirconium oxide (ZrO₂) layer, or a gadolinium oxide (Gd₂O₃) layer. In any case, the first blocking layer 142 has the first band gap of a relatively large value, and the second blocking layer 144 has the second band gap of a relatively small value. Therefore, the first blocking layer 142 prevents carriers from leaking from the charge trapping layer 130 to the second blocking layer 144.

A control gate electrode 150 is disposed on the blocking layer 140. The control gate electrode 150 may include a polysilicon layer heavily doped with n-type impurity ion. Also, the control gate electrode 150 may include a metal layer such as a tantalum nitride (TaN) layer. When the control gate electrode 150 is the metal layer, the metal layer has a work function of approximately 4.5 eV or higher. A low resistance layer 160 is disposed on the control gate electrode 150 in order to reduce a resistivity of a gate line. The low resistance layer 160 may include a tungsten nitride (WN)/tungsten (W) layer.

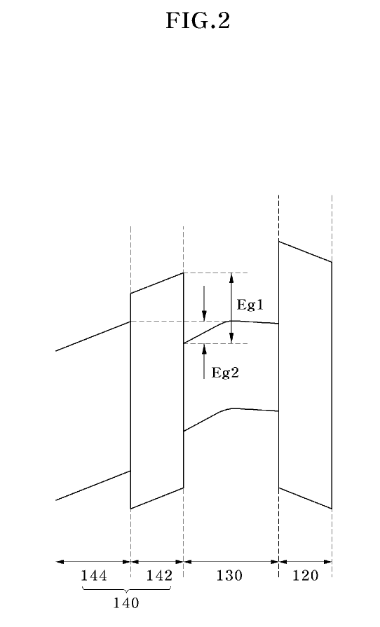

FIG. 2 is a band diagram of the nonvolatile memory device illustrated in FIG. 1. In FIGS. 1 and 2, like reference numerals refer to like elements. Referring to FIG. 2, a conduction band level of the charge trapping layer 130 is lower than that of the tunneling layer 120 or the blocking layer 140. Therefore, if the carriers trapped in the charge trapping layer 130 do not have energy higher than the difference of the conduction band levels, that is the band gap, the carriers will not leak toward the tunneling layer 120 or the blocking layer 140. If the second blocking layer 144 is formed of a high-k material, e.g., aluminum oxide (Al₂O₃), hafnium oxide (HfO₂), hafnium aluminum oxide (HfAlO), hafnium silicon oxide (HfSiO), hafnium lanthanum oxide (HfLaO), zirconium oxide (ZrO₂), or gadolinium oxide (Gd₂O₃), the second band gap (Eg2) defined by the difference of the conduction band level between the second blocking layer 144 and the charge trapping layer 130 is not sufficiently large. In this case, due to the second band gap (Eg2) having a small value relative to the first band gap (Eg1), the carriers trapped in the charge trapping layer 130 may leak out. However, by providing the first blocking layer 142 between the second blocking layer 144 and the charge trapping layer 130, the leakage of the carriers trapped in the charge trapping layer 130 is further suppressed. This is because that the first blocking layer 142 is formed of a material having the first band gap (Eg1) relatively larger than the second band gap (Eg2). That is, in the absence of the first blocking layer 142, the carriers trapped in the charge trapping layer 130 are highly likely to jump the relatively low second band gap (Eg2). However, due to the presence of the first blocking layer 142, the carriers trapped in the charge trapping layer 130 are not highly likely to jump the first band gap (Eg1).

An operation of the nonvolatile memory device 100 according to the embodiment of the present invention will be described below. In the program operation of the nonvolatile memory device 100, the control gate electrode 150 is positively charged and a proper bias is applied to the first impurity region 112 and the second impurity region 114. Hot electrons are generated in the channel region 116 of the substrate 110. The generated hot electrons are trapped in the trap sites within the charge trapping layer 120. In the device 100, the first blocking layer 142, having a high band gap with respect to the charge trapping layer 130, is disposed on the charge trapping layer 130, so that the electrons trapped in the charge trapping layer 120 are prevented from leaking toward the second blocking layer 144 by disposing.

In the erase operation of the device 100, the control gate electrode 150 is negatively charged and a proper bias is applied to the first impurity region 112 and the second impurity region 114. Holes existing in the channel region 116 of the substrate 110 are trapped in the trap sites within the charge trapping layer 130. The holes trapped in the charge trapping layer 130 are recombined with extra electrons existing in the trap sites. The read operation of the programmed or erased nonvolatile memory device 100 can be performed by sensing a threshold voltage that varies when the device 100 is programmed or erased.

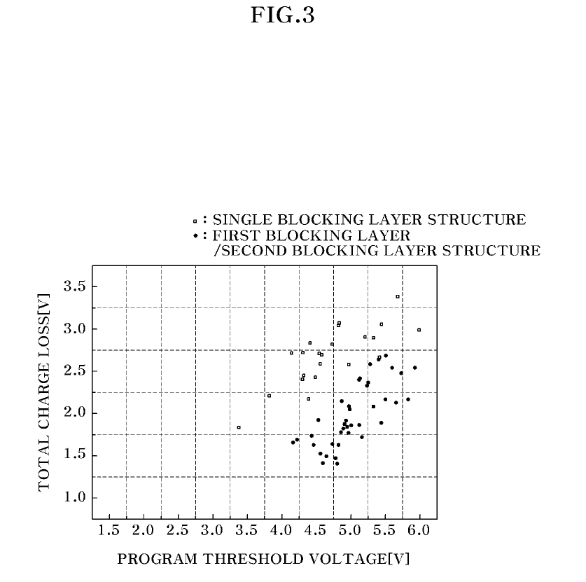

FIG. 3 is a graph showing a retention characteristic of the device 100 of FIG. 1. In FIG. 3, a horizontal axis and a vertical axis represent a program threshold voltage and a total charge loss, respectively. In FIG. 3, □ (square) represents the total charge loss distribution with respect to the program threshold voltage in the typical single blocking layer structure. The typical single blocking layer structure represents a structure where the blocking layer such as an aluminum oxide (Al₂O₃) layer is disposed on the charge trapping layer. In FIG. 3, (dark circle) represents the total charge loss distribution with respect to the program threshold voltage in the first blocking layer/second blocking layer structure according to the embodiment of the present invention. As can be seen from FIG. 3, the total charge loss of the first blocking layer/second blocking layer structure is less than that of the single blocking layer structure at any program threshold voltage. Therefore, the first blocking layer/second blocking layer structure exhibits a relatively excellent retention characteristic. As described above, this is because the first blocking layer having a relatively large band gap with respect to the charge trapping layer prevents the charges from leaking from the charge trapping layer to the second blocking layer.

A method for fabricating the nonvolatile memory device of FIG. 1 will be described below.

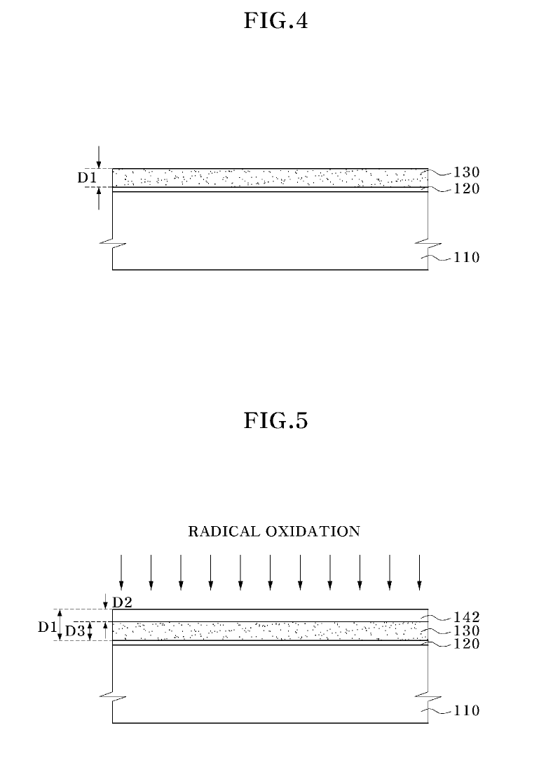

Referring to FIG. 4, a tunneling layer 120 is formed on a substrate 110. The tunneling layer 120 may be formed of an oxide layer by a wet oxidation process, a dry oxidation process, or a radical oxidation process. After forming the tunneling layer 120, an interface characteristic between the substrate 110 and the tunneling layer 120 can be enhanced by performing an annealing process in a NO or N₂O atmosphere. Then, a charge trapping layer 130 is formed on the tunneling layer 120. The charge trapping layer 130 has a thickness D1 greater than an intended thickness. For example, when the intended thickness of the charge trapping layer 130 is in a range from approximately 40 Å to approximately 120 Å, the charge trapping layer 130 is formed to a thickness ranging from approximately 70 Å to approximately 180 Å, which is thicker by approximately 30 Å to approximately 60 Å. Also, the charge trapping layer 130 may be formed to have a stacked structure of a stoichiometric silicon nitride (Si₃N₄) layer and a silicon-rich silicon nitride (SiₓN_{y}) layer. In this case, the stoichiometric silicon nitride (Si₃N₄) layer may be first formed, or the silicon-rich silicon nitride (SiₓN_{y}) layer may be first formed. Furthermore, the charge trapping layer 130 may be formed to have a stacked structure of a lower stoichiometric silicon nitride (Si₃N₄) layer, a silicon-rich silicon nitride (SiₓN_{y}) layer, and an upper stoichiometric silicon nitride (Si₃N₄) layer. In any case, when the silicon-rich silicon nitride (SiₓN_{y}) layer is used, the composition ratio (x:y) of silicon (Si) to nitride (N) in the silicon-rich silicon nitride (SiₓN_{y}) layer is in a range from approximately 1:0.8 to approximately 1:1.3. A deep trap site exists in the charge trapping layer 130, which degrades the storage capability. On the contrary, if the silicon (Si) composition ratio increases, silicon dangling bond occurs and thus the number of shallow trap sites increases, thereby increasing the storage capability.

Referring to FIG. 5, a first blocking layer 142 is formed by performing an oxidation process on the surface of the charge trapping layer 130. The oxidation process may be performed using a radical oxidation process. When the typical process of depositing an oxide layer is performed without using the oxidation process, unintended trap sites may be formed on the interface between the first blocking layer 142 and the charge trapping layer 130. In addition, unnecessary charges exist in the deposited oxide layer itself. These unnecessary charges reduce a coupling ratio, thus causing the threshold voltage distortion in the program or erase operation. However, this problem can be solved by forming the first blocking using the oxidation process such as the radical oxidation process.

In order to perform the oxidation process using the radical oxidation process, the substrate 110 with the charge trapping layer 130 formed thereon is loaded into a chamber. The chamber is maintained in a mixed atmosphere of hydrogen (H₂) and oxygen (O₂) at a pressure range of approximately 0.1 torr to approximately 10 torr at a temperature range of approximately 800° C. to approximately 900° C. The concentrations of the radicals such as H*, O* and OH* can be maintained at a high level within the chamber. These radicals have strong oxidative properties and maintain a constant oxidation rate independently of the orientation of silicon (Si). Therefore, the radicals oxidize the upper portion of the charge trapping layer 130 by a predetermined thickness D2. Consequently, the first blocking layer 142 is formed on the upper portion of the charge trapping layer 130 by oxidizing a portion of the charge trapping layer 130. In the previous step, where the thickness D1 of the charge trapping layer 130 is approximately 70 Å to approximately 180 Å, the thickness D2 of the first blocking layer 142 is approximately 30 Å to approximately 60 Å. Thus, the final thickness D3 of the charge trapping layer 130 is approximately 40 Å to approximately 120 Å. Where the charge trapping layer 130 is formed of silicon nitride, the first blocking layer 142 becomes a silicon oxynitride (SiON) layer. As described above with reference to FIG. 2, the silicon oxynitride (SiON) layer, which is the first blocking layer 142 has a large band gap with respect to the silicon nitride layer used as the charge trapping layer 130, compared with an aluminum oxide (Al₂O₃) layer generally used as the blocking layer. Therefore, electrons trapped in the charge trapping layer 130 can be further suppressed from leaking toward the blocking layer.

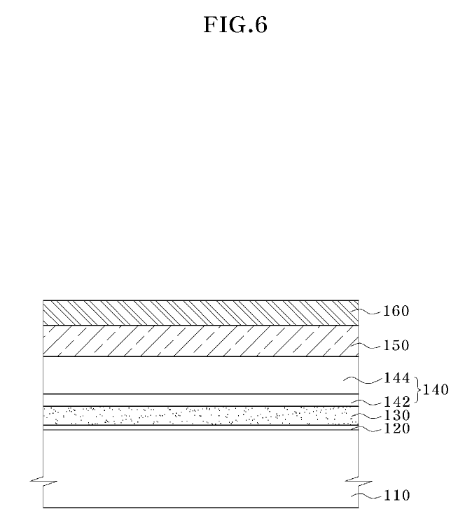

Referring to FIG. 6, a second blocking layer 144 is formed on the first blocking layer 142. The second blocking layer 144 is formed of aluminum oxide (Al₂O₃) to a thickness ranging from approximately 50 Å to approximately 300 Å. The aluminum oxide (Al₂O₃) layer may be formed using an atomic layer deposition (ALD) process. Also, the second blocking layer 144 may be formed of hafnium (Hf) based oxide by an ALD process. Examples of the hafnium (Hf) based oxide include hafnium oxide (HfO₂), hafnium aluminum oxide (HfAlO), and hafnium silicon oxide (HfSiO). In addition, the second blocking layer 144 may be formed of zirconium oxide (ZrO₂) or gadolinium oxide (Gd₂O₃). After forming the second blocking layer 144, the layer quality of the second blocking layer 144 can be enhanced by performing a rapid thermal processing (RTP) within the chamber in a nitrogen atmosphere or a vacuum atmosphere or by performing an annealing process in a furnace. The second blocking layer 144 and the first blocking layer 142 is used as a blocking layer 140 for insulating the charge trapping layer 130 from the control gate electrode 150.

After forming the second blocking layer 144, the control gate electrode 150 is formed on the second blocking layer 144. A low resistance layer 160 is formed on the control gate electrode 150. The control gate electrode 150 may include a polysilicon layer heavily doped with n-type impurity. Also, the control gate electrode 150 may be formed of a metal gate having a work function of approximately 4.5 eV or higher, for example, a tantalum nitride (TaN) layer, a titanium nitride (TiN), or a tungsten nitride (WN) layer. The low resistance layer 160 reduces a resistivity of a word line and has a tungsten nitride (WN)/tungsten (W) structure. Then, a typical patterning process is performed and an impurity region is formed by ion implantation. In this way, the nonvolatile memory device of FIG. 1 is fabricated.

According to the embodiments of the present invention, by disposing the first blocking layer having a relative large band gap between the charge trapping layer and the second blocking layer, it is possible to prevent electrons from leaking from the charge trapping layer to the second blocking layer. Therefore, the retention characteristic and the cycling characteristic can be enhanced. Furthermore, by forming the first blocking layer using the radical oxidation process on the upper portion of the charge trapping layer, instead of the typical deposition process, it is possible to prevent unintended trap sites from being formed in the first blocking layer, thereby enhancing the operation characteristics, such as the program or erase operation.

While the present invention has been described with respect to the specific embodiments, it will be apparent to those skilled in the art that various changes and modifications may be made without departing from the spirit and scope of the invention as defined in the following claims.

What is claimed is:

1. A nonvolatile memory device, comprising:
a substrate;
a tunneling layer over the substrate;
a charge trapping layer over the tunneling layer;
a first blocking layer over the charge trapping layer;
a second blocking layer over the first blocking layer; and,
a control gate electrode over the second blocking layer, wherein a first band gap between the first blocking layer and the charge trapping layer is larger than a second band gap between the second blocking layer and the charge trapping layer.

2. The nonvolatile memory device of claim 1, wherein the charge trapping layer comprises a stoichiometric silicon nitride (Si₃N₄) layer.

3. The nonvolatile memory device of claim 1, wherein the charge trapping layer has a stacked structure of a stoichiometric silicon nitride (Si₃N₄) layer and a silicon-rich silicon nitride (SiₓN_{y}) layer.

4. The nonvolatile memory device of claim 3, wherein a composition ratio (x:y) of silicon (Si) to nitride (N) in the silicon-rich silicon nitride (SiₓN_{y}) layer is in a range from approximately 1:0.8 to approximately 1:1.3.

5. The nonvolatile memory device of claim 1, wherein the charge trapping layer has a stacked structure of a lower stoichiometric silicon nitride (Si₃N₄) layer, a silicon-rich silicon nitride (SiₓN_{y}) layer, and an upper stoichiometric silicon nitride (Si₃N₄) layer.

6. The nonvolatile memory device of claim 5, wherein a composition ratio (x:y) of silicon (Si) to nitride (N) in the silicon-rich silicon nitride (SiₓN_{y}) layer is in a range from approximately 1:0.8 to approximately 1:1.3.

7. The nonvolatile memory device of claim 1, wherein the charge trapping layer has a thickness ranging from approximately 40 Å to approximately 100 Å.

8. The nonvolatile memory device of claim 1, wherein the first blocking layer comprises a silicon oxynitride (SiON) layer.

9. The nonvolatile memory device of claim 8, wherein the silicon oxynitride (SiON) layer has a thickness ranging from approximately 30 Å to approximately 60 Å.

10. The nonvolatile memory device of claim 1, wherein the second blocking layer comprises an aluminum oxide (Al₂O₃) layer having a thickness ranging from approximately 50 Å to approximately 300 Å.

11. The nonvolatile memory device of claim 1, wherein the second blocking layer comprises a hafnium oxide (HfO₂) layer, a hafnium aluminum oxide (HfAlO) layer, a hafnium silicon oxide (HfSiO) layer, a hafnium lanthanum oxide (HfLaO) layer, a zirconium oxide (ZrO₂) layer, or a gadolinium oxide (Gd₂O₃) layer.

12. The nonvolatile memory device of claim 1, wherein the control gate electrode comprises a polysilicon layer heavily doped with n-type impurity ion.

13. The nonvolatile memory device of claim 1, wherein the control gate electrode comprises a metal layer having a work function of approximately 4.5 eV or higher.

14. The nonvolatile memory device of claim 13, wherein the metal layer comprises tantalum nitride (TaN), titanium nitride (TiN), or tungsten nitride (WN).

15. The nonvolatile memory device of claim 1, further comprising a low resistance layer on the control gate electrode.

16. The nonvolatile memory device of claim 15, wherein the low resistance layer comprises a tungsten nitride/tungsten (WN/W) structure.

17. A nonvolatile memory device, comprising:
a silicon substrate;
an oxide layer over the silicon substrate;
a silicon nitride layer over the oxide layer;
a silicon oxynitride layer and an aluminum oxide layer over the silicon nitride layer; and,
a polysilicon layer over the aluminum oxide layer.

18. A nonvolatile memory device, comprising:
a silicon substrate;
an oxide layer over the silicon substrate;
a silicon nitride layer over the oxide layer;
a silicon oxynitride layer and an aluminum oxide layer over the silicon nitride layer; and,
a metal layer over the aluminum oxide layer.

19. A method for fabricating a nonvolatile memory device, the method comprising:
forming a tunneling layer over a substrate;
forming a charge trapping layer over the tunneling layer;
forming a first blocking layer over the charge trapping layer;
forming a second blocking layer over the first blocking layer; and,
forming a control gate electrode over the second blocking layer, wherein a first band gap between the first blocking layer and the charge trapping layer is larger than a second band gap between the second blocking layer and the charge trapping layer.

20. The method of claim 19, wherein the charge trapping layer comprises a stoichiometric silicon nitride (Si₃N₄) layer.

21. The method of claim 19, wherein the charge trapping layer has a stacked structure of a stoichiometric silicon nitride (Si₃N₄) layer and a silicon-rich silicon nitride (SiₓN_{y}) layer.

22. The method of claim 21, wherein a composition ratio (x:y) of silicon (Si) to nitride (N) in the silicon-rich silicon nitride (SiₓN_{y}) layer is in a range from approximately 1:0.8 to approximately 1:1.3.

23. The method of claim 19, wherein the charge trapping layer has a stacked structure of a lower stoichiometric silicon nitride (Si₃N₄) layer, a silicon-rich silicon nitride (SiₓN_{y}) layer, and an upper stoichiometric silicon nitride (Si₃N₄) layer.

24. The method of claim 23, wherein a composition ratio (x:y) of silicon (Si) to nitride (N) in the silicon-rich silicon nitride (SiₓN_{y}) layer is in a range from approximately 1:0.8 to approximately 1:1.3.

25. The method of claim 19, wherein the charge trapping layer has a thickness ranging from approximately 40 Å to approximately 100 Å.

26. The method of claim 19, wherein the first blocking layer is formed by performing a radical oxidation process on an upper surface of the charge trapping layer.

27. The method of claim 26, wherein the first blocking layer comprises a silicon oxynitride (SiON) layer.

28. The method of claim 27, wherein the silicon oxynitride (SiON) layer has a thickness ranging from approximately 30 Å to approximately 60 Å.

29. The method of claim 26, wherein the radical oxidation process is performed in a mixed atmosphere of hydrogen (H₂) and oxygen (O₂) at a pressure range of approximately 0.1 torr to approximately 10 torr at a temperature range of approximately 800° C. to approximately 900° C.

30. The method of claim 19, wherein the second blocking layer comprises an aluminum oxide (Al₂O₃) layer having a thickness ranging from approximately 50 Å to approximately 300 Å.

31. The method of claim 30, wherein the aluminum oxide layer is formed using an atomic layer deposition (ALD) process.

32. The method of claim 19, wherein the second blocking layer comprises a zirconium oxide (ZrO₂) layer, a gadolinium oxide (Gd₂O₃) layer, or a hafnium based oxide layer selected from the group consisting of a hafnium oxide (HfO₂) layer, a hafnium aluminum oxide (HfAlO) layer, a hafnium silicon oxide (HfSiO) layer, and a hafnium lanthanum oxide (HfLaO) layer.

33. The method of claim 19, further comprising, after the forming of the second blocking layer, performing an annealing process in a nitrogen atmosphere or a vacuum atmosphere.

34. The method of claim 19, wherein the control gate electrode comprises a polysilicon layer heavily doped with n-type impurity ion.

35. The method of claim 19, wherein the control gate electrode comprises a metal layer having a work function of approximately 4.5 eV or higher.

36. The method of claim 19, further comprising forming a low resistance layer on the control gate electrode.

37. The method of claim 36, wherein the low resistance layer comprises a tungsten nitride/tungsten (WN/W) structure.

38. A method for fabricating a nonvolatile memory device, the method comprising:
forming a tunneling layer over a substrate;
forming a charge trapping layer over the tunneling layer;
oxidizing the charge trapping layer by a predetermined thickness to form a first blocking layer;
forming a second blocking layer over the first blocking layer; and
forming a control gate electrode over the second blocking layer.

39. The method of claim 38, wherein the oxidizing step comprises a radial oxidation process.
